(19) United States
(12) Patent Application Publication
(10) Pub. No.: US 2010/0270651 A1
(43) Pub. Date: Oct. 28, 2010

(54) Sapphire substrate with periodical structure

(75) Inventors: Chung-Hua Li, Taipei City (TW); Sheng-Ru Lee, Taipei City (TW)

Correspondence Address: BACON & THOMAS, PLLC, 625 SLATERS LANE, FOURTH FLOOR, ALEXANDRIA, VA, 22314-1176, US

(73) Assignee: Aurotek Corporation, Taipei (TW)

(21) Appl. No.: 12/662,544

(22) Filed: Apr. 22, 2010

(30) Foreign Application Priority Data
Apr. 27, 2009 (TW) 098113870

(51) Int. Cl. H01L 29/30; H01L 21/306

(52) U.S. Cl. 257/618; 438/689; 257/E29.106; 257/E21.215

(57) ABSTRACT

A sapphire substrate with periodical structure is disclosed, which comprises: a sapphire substrate, and at least one periodical structure formed on at least one surface of the sapphire substrate and having plural micro-cavities; wherein, the micro-cavities are arranged in an array, the micro-cavities are each in an inverted awl-shape, the length of the base line of the micro-cavities is 100˜2400 nm, and the depth of the micro-cavities is 25˜1000 nm.

### BACKGROUND OF THE INVENTION

1. Field of the Invention

The present invention relates to a sapphire substrate with a periodical structure and, more particularly, to a sapphire substrate with a periodical structure formed by nano-sized balls, which can be used in light emitting diodes (LEDs).

2. Description of Related Art

FIG. 1 is a perspective view of a general light emitting diode (LED). The LED is co-operated with an external electronic circuit (not shown in the figure) to transform electricity into light. Generally, the LED comprises: a substrate 10, a buffer layer 131 disposed on the surface of the substrate 10, a first semiconductor layer 13 disposed on the surface of the buffer layer 131, an active layer 14 disposed on the surface of the first semiconductor layer 13, a second semiconductor layer 15 disposed on the surface of the active layer 14, a first electrical contacting part 16 electrically connected to the first semiconductor layer 13, and a second electrical contacting part 17 electrically connected to the second semiconductor layer 15.

For example, a blue LED is produced by the substrate 10 made of sapphire using a flip-chip technology. When the light emits from the active layer 14 and passes through the substrate 10, the phenomenon of internal total reflection is caused due to the flat out-light surface of the sapphire substrate. Hence, the quantum efficiency of the blue LED is decreased. Therefore, a roughening treatment, i.e. patterning, is performed on the out-light surface of the sapphire substrate, to eliminate the angles of total reflection and improve the light extraction.

In addition, GaN is one kind of semiconductor material, which can generate blue light efficiently. However, when GaN is deposited on the surface of the sapphire substrate 10 as a buffer layer 131, a lot of defects exist between the buffer layer 131 and the substrate 10 due to the large differences of the lattice constant between sapphire and GaN. These defects cause the light emitting efficiency to be decreased and the probability of electrical leakage to be increased. In order to reduce difference of the lattice constant between sapphire and GaN, a patterning process is performed on the sapphire substrate. Compared to the flat surface of the sapphire substrate, the lattice constant of the patterned surface of the sapphire substrate is very similar to that of GaN. Thus, when GaN is deposited on the patterned surface of the sapphire substrate, an epitaxial thin film with better quality is obtained. When this patterned sapphire substrate with GaN thin film formed thereon is applied to an LED, the power of the LED can be improved.

Currently, the patterned surface of the sapphire substrate is formed though photolithography and followed by wet etching or dry etching. The process for patterning the sapphire substrate is shown in FIGS. 2A to 2F. First, referring to FIG. 2A, a substrate 10 is provided; and a photo-resist layer 11 is formed on the surface 101 of the substrate 10, as shown in FIG. 2B. Next, a photo-mask 12 is provided on the photo-resist layer 11, followed by exposing to pattern the photo-resist layer 11, as shown in FIG. 2C. After developing and removing the photo-mask 12, a patterned photo-resist layer 11 is obtained, as shown in FIG. 2D. A reactive ion etching (RIE) process is performed to etch the substrate 10 by using the patterned photo-resist layer 11 as an etching template, and then plural micro-cavities 102 are formed on the surface of the substrate 10, as shown in FIG. 2E. After removing the photo-resist layer 11 (etching template), a patterned substrate 10 is obtained, as shown in FIG. 2F. Herein, the plural micro-cavities formed on the surface 101 of the patterned substrate 10 are arranged in a periodical structure.

Although the method of dry etching can produce a substrate having a periodical structure with uniform and regular micro-cavities, there are still some disadvantages with the aforementioned process. First, the manufacturing cost of photolithography is high and the production rate is low. Further, if a nano-sized periodical structure is desired, a photo-mask with sub-micro size is required in the photolithography process. However, the photo-mask with sub-micro size is very expensive, and the manufacturing cost of the photo-mask is even more expensive when a periodical structure with a size of 500 nm or less is desired. In addition, the RIE machine is expensive, the RIE process is slow, and the substrate is damaged easily when the RIE process is used. Moreover, the etching surface formed through the dry etching process, i.e. the surface of the patterned substrate, is an unnatural lattice plane, which cannot match with the GaN thin film ideally.

In order to solve the problem caused by the dry etching process, a method of wet etching is developed to form a substrate with a periodical structure, as shown in FIGS. 3A to 3F. The wet etching process for forming a substrate with a periodical structure is similar to the dry etching process, except an etching buffer is used to pattern the substrate. First, a substrate 10 is provided, as shown in FIG. 3A. Next, a glass layer 18 is formed on the surface of the substrate 10, followed by coating a photo-resist layer 11 on the glass layer 18, as shown in FIG. 3B. Then, a photo-mask 12 is disposed on the surface of the photo-resist layer 11, followed by exposing, and a patterned photo-resist layer 11 is obtained, as shown in FIG. 3C. After removing the photo-mask 12 and developing the patterned photo-resist layer 11, an etching buffer is used to pattern the glass layer 18 by applying the patterned photo-resist layer 11 as an etching template, as shown in FIG. 3D. Then, the patterned glass layer 18 serves as another etching template for patterning the substrate 10, and the substrate 10 is patterned by another etching buffer, as shown in FIG. 3E. Finally, the patterned photo-resist layer 11 and the patterned glass layer 18 are removed to obtain a patterned substrate 10, as shown in FIG. 3F. Herein, the plural micro-cavities 102 formed on the surface 101 of the patterned substrate 10 are arranged in a periodical structure. When the substrate 10 is patterned by a wet etching process, the micro-cavities 102 with inverted awl-shape are obtained.

The wet etching process can protect the substrate from damage and the surface of the patterned substrate is a natural lattice plane, but the uniformity of the periodical structure is not good enough if the parameter of the wet etching process is not controlled properly. In addition, the photolithography is still performed in the aforementioned process, so the problems of high manufacturing cost and low production rate still exist.

Therefore, it is desirable to provide a sapphire substrate with a patterned surface, which has a consistent lattice constant with GaN, in order to reduce the phenomenon of total reflection and improve the brightness of LEDs. In addition, although the process combining photolithography with wet etching can obtain a sapphire substrate with a patterned surface, high manufacturing cost and low production rate still cause the manufacturing cost of blue LEDs unable to be reduced. Therefore, it is desirable to provide a patterned sapphire, which can be produced rapidly and inexpensively.

### SUMMARY OF THE INVENTION

The object of the present invention is to provide a sapphire substrate with a periodical structure, wherein the lattice constant of the sapphire substrate of the present invention is consistent with that of GaN to improve the brightness of LEDs.

To achieve the object, the sapphire substrate with the periodical structure of the present invention comprises: a sapphire substrate; and at least one periodical structure formed on at least one surface of the sapphire substrate, and having plural micro-cavities. The micro-cavities are arranged in an array, the micro-cavities are each in an inverted awl-shape, the length of the base line of the micro-cavities is 100˜2400 nm, and the depth of the micro-cavities is 25˜1000 nm. Herein, the inverted awl means that the base of the awl is located on the surface of the sapphire substrate, and the apex of the awl is hollowed from the surface of the sapphire substrate. In addition, the sapphire substrate of the present invention may have one periodical structure formed on one surface thereof, or have two periodical structures formed on both surfaces thereof.

According to the sapphire substrate with the periodical structure of the present invention, preferably, the periodical structure is formed by the following steps: (A) providing the sapphire substrate and plural nano-sized balls, wherein the nano-sized balls are arranged on a surface of the sapphire substrate; (B) depositing a cladding layer on partial surface of the sapphire substrate and the gaps between the nano-sized balls; (C) removing the nano-sized balls; (D) etching the sapphire substrate by using the cladding layer as an etching template; and (E) removing the etching template to form the periodical structure on the surface of the sapphire substrate.

According to the sapphire substrate with the periodical structure of the present invention, the nano-sized balls are used for replacing the process of photolithography to form the periodical structure. The nano-sized balls can arranged automatically and uniformly on the surface of the sapphire substrate, due to the property of “self-assembling” of the nano-sized balls. The well-arranged nano-sized balls can serve as a template for forming an etching template. The sapphire substrate of the present invention is produced by the arranged nano-sized balls, not by the expensive photo-mask with sub-micro size. Hence, it is possible to produce the sapphire substrate with the periodical structure inexpensively and rapidly in the present invention. The size of the inverted awl-shaped micro-cavities is adjusted by the condition of the etching process and the size of the nano-sized balls. The length of the base of the micro-cavities may be 100 nm˜2400 nm, and the depth of the micro-cavities may be 25 nm˜1000 nm. Preferably, the length of the base of the micro-cavities is 100 nm˜1000 nm, and the depth of the micro-cavities is 25 nm˜500 nm.

According to process for forming the periodical structure on the sapphire substrate of the present invention, after the step (E), the process of the present invention further comprises a step (F): re-etching the surface of the sapphire substrate.

According to the sapphire substrate of the present invention, there may be a plane between the adjacent micro-cavities, and the plane is in a same elevation. Hence, the aforementioned sapphire substrate with the periodical structure can be regarded as a concaved sapphire substrate. In addition, there may be no plane between the adjacent micro-cavities, so this sapphire substrate with the periodical structure can be regarded as a convex sapphire substrate. Therefore, the sapphire substrate of the present invention may be in a concave form, a convex form, a concavo-concave form, a concavo-convex form, or a convexo-convex form.

The sapphire substrate of the present invention may further comprise an epitaxial thin film formed on the surface of the sapphire substrate and the surfaces of the micro-cavities. Preferably, the epitaxial thin film is an epitaxial GaN thin film. The periodical structure on the surface of the sapphire substrate is consistent with the lattice constant of GaN, so it is possible to form an epitaxial GaN thin film with good quality. Hence, when the sapphire substrate of the present invention is applied to LEDs, the power of the LEDs can be improved.

According to the process for forming the periodical structure on the sapphire substrate of the present invention, the step (A) of arranging the nano-sized balls on the surface of the sapphire substrate comprises the following steps: (A1) providing the sapphire substrate, and a colloid solution in a container, wherein the colloid solution comprises the nano-sized balls and a surfactant; (A2) placing the sapphire substrate in the container, and the colloid solution covering the surface of the sapphire substrate; and (A3) adding a volatile solution into the container to obtain the sapphire substrate with the nano-sized balls formed thereon. Herein, the nano-sized balls are formed into nano-sized ball layers, and formed into a layer of nano-sized ball layer, preferably.

According to the sapphire substrate of the present invention, the size of the micro-cavities is determined by the size of the nano-sized balls and the condition of etching. Preferably, the diameter of the nano-sized balls is 100 nm˜2.5 μm. More preferably, the diameter of the nano-sized balls is 100 nm˜1.2 μm. In addition, the diameters of all the nano-sized balls are the same, preferably. Furthermore, the material of the nano-sized balls is not limited, and may be silicon oxides, ceramics, PMMA, titanium oxides, or PS.

According to the sapphire substrate of the present invention, the material of the cladding layer can divided into metal or glass material. Further, the metal or glass material can be deposited on partial surface of the sapphire substrate and the gaps between the nano-sized balls by use of a general thin film deposition apparatus or a general electrochemical deposition apparatus. Preferably, the cladding layer is formed through chemical vapor deposition (CVD) or physical vapor deposition (PVD). In addition, the metal material used in the cladding layer can be any material generally used for etching templates. Preferably, the metal material is Cr, Ta, W, V, Ni, Fe, Ag, Au, Pt, or Pd. The main component of the glass material used in the cladding layer can be silicon oxides, silicon nitrides, silicon oxynitrides, or silicon oxides doped with alkaline metal, alkaline-earth metal, or other metal ions. Preferably, the main component of the glass material is silicon oxides. Further, the thickness of the cladding layer is adjusted according to the size of the desired micro-cavities. Preferably, the thickness of the cladding layer is shorter than the diameter of the nano-sized balls.

According to process for forming the periodical structure on the sapphire substrate of the present invention, the process of dry etching or wet etching can be used for etching the sapphire substrate in the step (D). Preferably, the process of wet etching is used to prevent the sapphire substrate from damage. Further, the solution containing sulfuric acid, phosphoric acid, or the combination thereof can be used as an etching buffer to pattern the sapphire substrate.

As the etching time and etching temperature differs, the size and the gaps of the array arranged by the micro-cavities are different. After the etching process is finished, the etching template is removed to obtain the sapphire substrate with the array arranged by the plural micro-cavities, i.e. the sapphire substrate with the periodical structure. The solution used for removing the etching template is selected according to the material of the cladding layer. A solution consisting of pure water and hydrofluoric acid (HF) is used for removing the cladding layer made of a glass material; and a solution consisting of pure water and phosphoric acid (H₃PO₄) is used for removing the cladding layer made of silicon nitride or the like. When the material of the cladding layer is Au, Pt, Pd, or Cr, the cladding layer can be removed by a solution consisting of nitric acid (H₂NO₄) and hydrochloric acid (HCl). When the material of the cladding layer is Ta, W, V, or Ni, the cladding layer can be removed by a solution consisting of H₂NO₄ and HF. When the material of the cladding layer is Fe, the cladding layer can be removed by a solution consisting of H₂NO₄ and HCl. Further, when the material of the cladding layer is Ag, the cladding layer can be removed by a solution consisting of H₂NO₄, or a mixture consisting of ammonia and hydroperoxide.

The sapphire substrate with the periodical structure of the present invention is formed by using nano-sized balls and wet etching process, not by photolithography. Hence, the photo mask with sub-micro size is not needed when preparing the sapphire substrate of the present invention, so it is possible to reduce the manufacturing cost and the production time greatly. At the same time, the periodical structure having plural micro-cavities is formed by a wet etching process, so it is possible to prevent the sapphire substrate from being damaged. Hence, the present invention provides the sapphire substrate with the periodical structure, which can be formed easily and inexpensively. Further, the periodical structure formed on the surface of the sapphire substrate is consistent with the lattice constant of an expitaxial GaN thin film, so the brightness of LEDs can be improved and the phenomenon of total reflection can be eliminated when the sapphire substrate with the periodical structure of the present invention is applied to LEDs.

In addition, the present invention further provides a sapphire substrate having an etching template with a periodical structure, comprising: a sapphire substrate; and an etching template, disposed on a surface of the sapphire substrate. Wherein, the etching template has a periodical structure formed on the surface of the etching template and having plural micro-cavities, and the micro-cavities are arranged in an array.

According to the sapphire substrate having the etching template with the periodical structure of the present invention, the shape of the micro-cavities may be a partial sphere. Preferably, the micro-cavities are in half-sphere shape. In addition, the diameters of the micro-cavities may be 100 nm˜2400 nm. Preferably the diameters of the micro-cavities are 100 nm˜1000 nm. Furthermore, the material of the etching template may be silicon oxides, silicon nitrides, silicon oxynitrides, silicon oxides doped with alkaline metal, silicon oxides doped with alkaline-earth metal, Cr, Ta, W, V, Ni, Fe, Ag, Au, Pt, or Pd.

Hence, it is possible to form micro-cavities with different shapes by using the sapphire substrate having the etching template with the periodical structure of the present invention, through adjusting the time, the temperature, and the etching buffer during the etching process. Therefore, the patterned sapphire substrate prepared from the sapphire substrate having the etching template of the present invention can be applied to LEDs in different purposes.

Other objects, advantages, and novel features of the invention will become more apparent from the following detailed description when taken in conjunction with the accompanying drawings.

### BRIEF DESCRIPTION OF THE DRAWINGS

FIG. 1 is a perspective view of a general light emitting diode;

FIGS. 2A to 2F are cross-sectional views illustrating a process for manufacturing a substrate with a periodical structure by use of a dry etching method in the art;

FIGS. 3A to 3F are cross-sectional views illustrating a process for manufacturing a substrate with a periodical structure by use of non-isotropic wet etching method in the art;

FIGS. 4A to 4F are cross-sectional views illustrating a process that nano-sized balls are arranged on a surface of a sapphire substrate in a preferred embodiment of the present invention;

FIGS. 5A to 5F are cross-sectional views illustrating a process for manufacturing a sapphire substrate with a periodical structure in a preferred embodiment of the present invention;

FIG. 6 is a perspective view of a sapphire substrate with a concave periodical structure of a preferred embodiment of the present invention;

FIG. 7 is a perspective view of a sapphire substrate with a convex periodical structure of a preferred embodiment of the present invention;

FIG. 8 is a perspective view of a sapphire substrate with a periodical structure of another preferred embodiment of the present invention;

FIG. 9 is a perspective view of a sapphire substrate with a periodical structure of still another preferred embodiment of the present invention; and

FIG. 10 is a perspective view of a sapphire substrate with a periodical structure of still another preferred embodiment of the present invention.

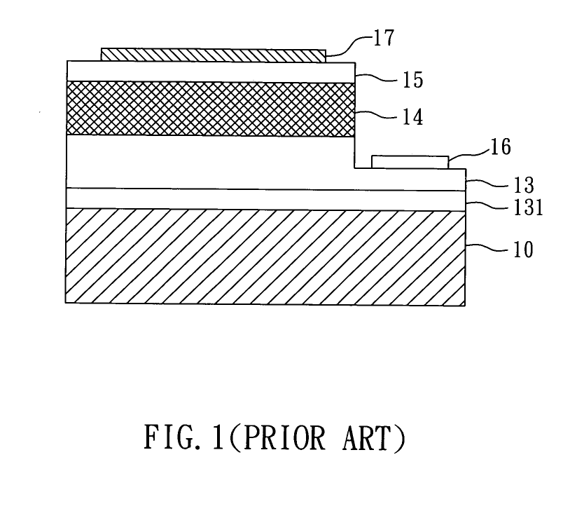

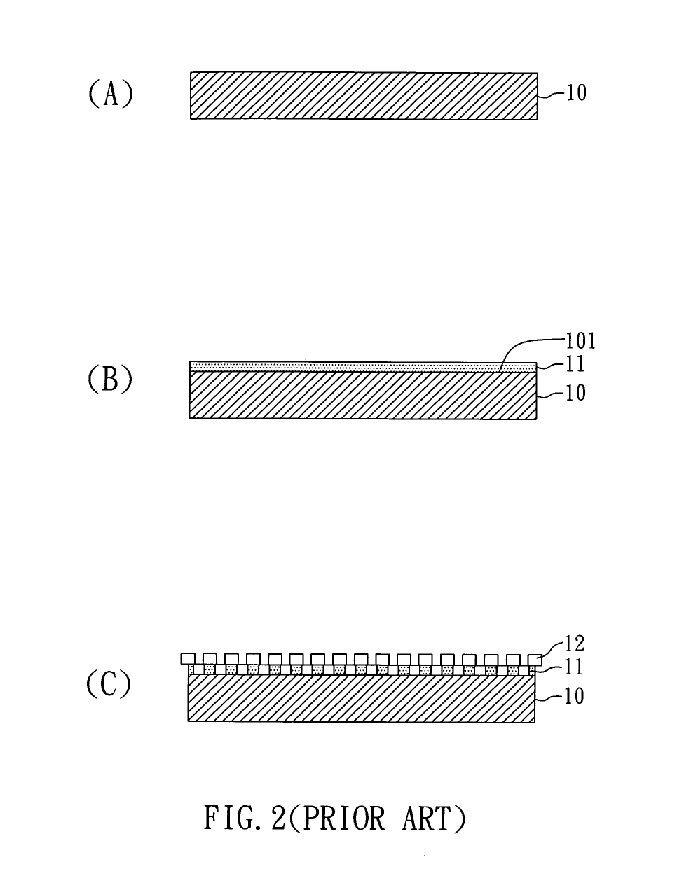

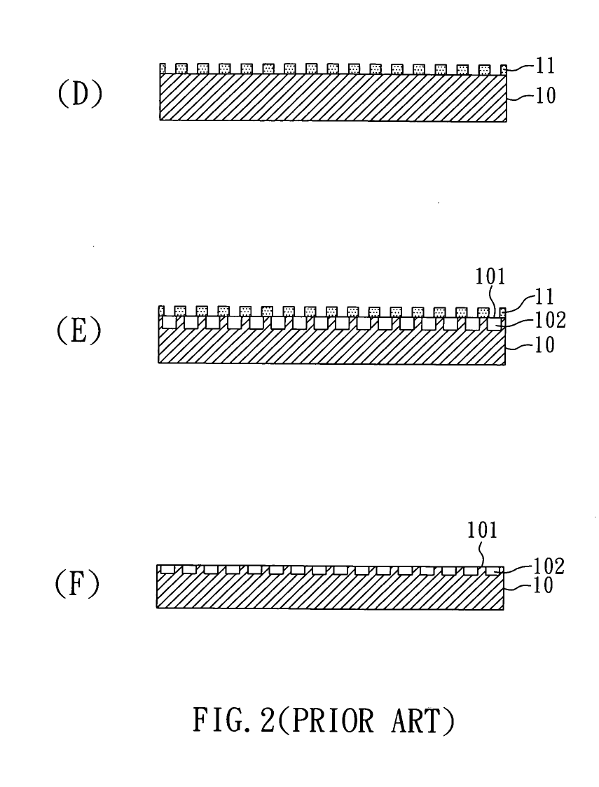

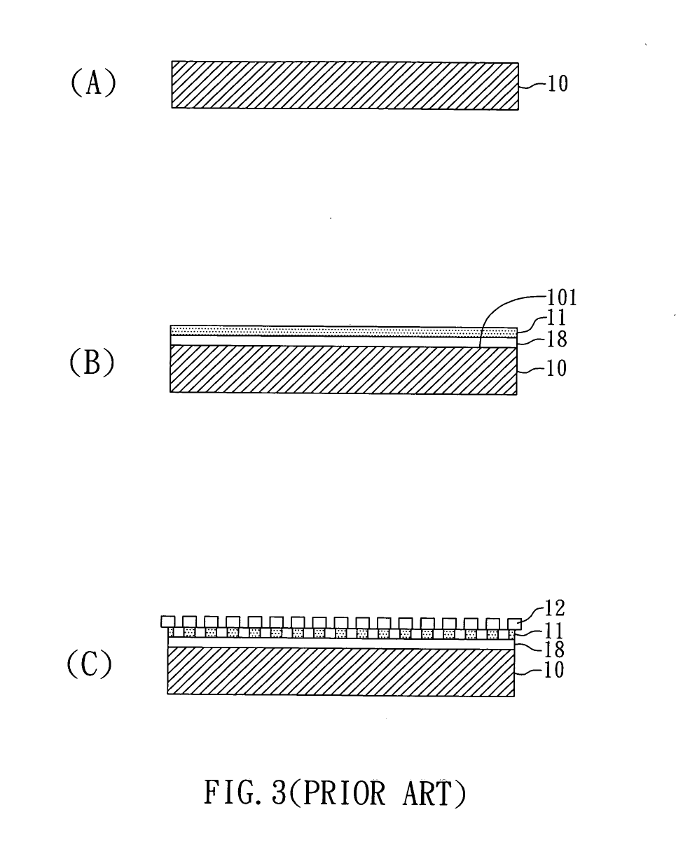

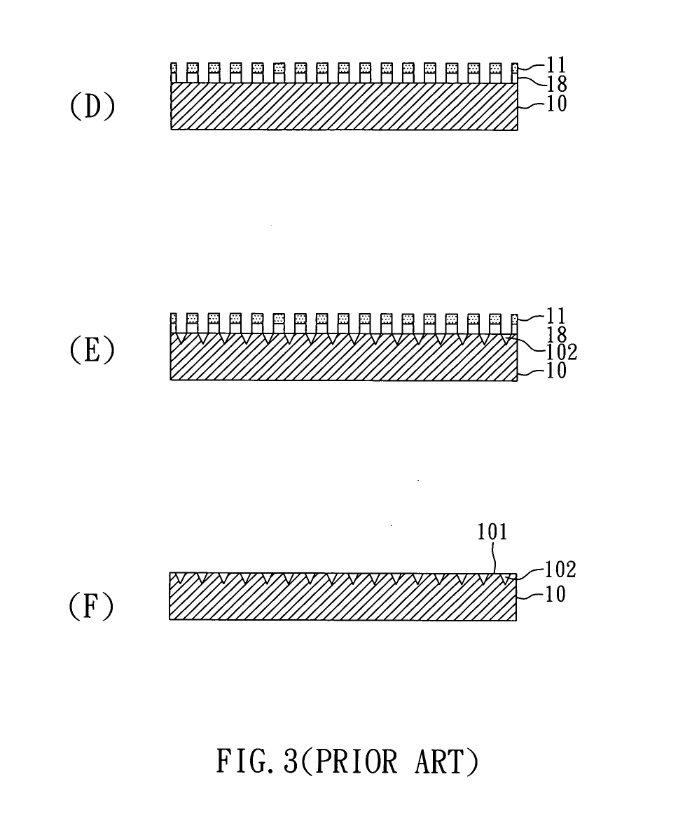

### DETAILED DESCRIPTION OF THE PREFERRED EMBODIMENT

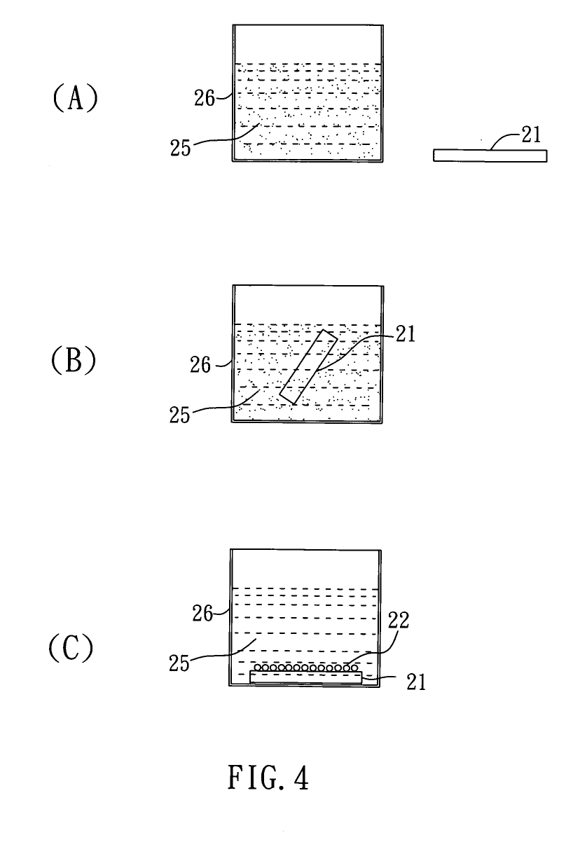

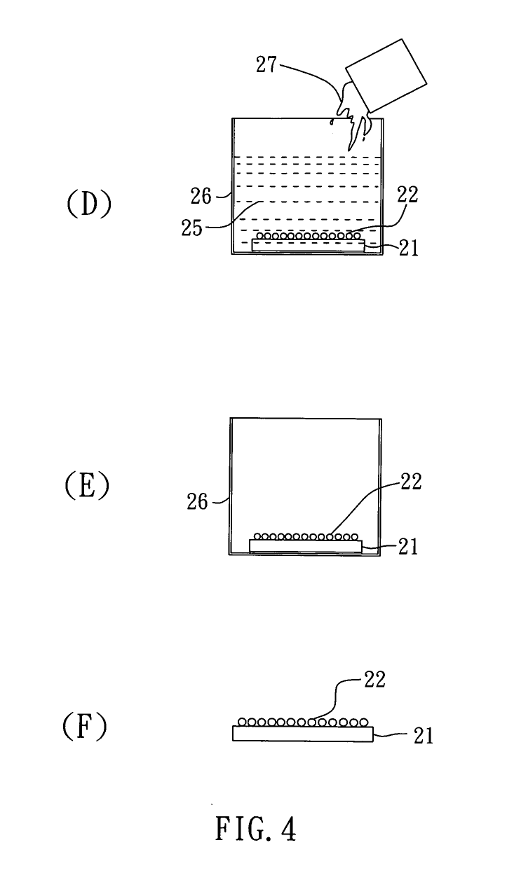

FIGS. 4A to 4F are cross-sectional views illustrating a process that nano-sized balls are arranged on a surface of a sapphire substrate in a preferred embodiment of the present invention. First, as shown in FIG. 4A, a sapphire substrate 21 is provided, and a colloid solution 25 is provided in a container 26, wherein the colloid solution 25 comprises plural nano-sized balls (not shown in the figure) and a surfactant (not shown in the figure). Next, the sapphire substrate 21 is placed in the container 26, and the sapphire substrate 21 is immersed in the colloid solution 25 entirely, as shown in FIG. 4B. After several minutes, the nano-sized balls 22 are arranged on the surface of the substrate 21 orderly to form a “nano-sized ball layer”, as shown in FIG. 4C. Then, a volatile solution 27 is added into the container 26 to evaporate the colloid solution 25 totally, as shown in FIG. 4D. Finally, after the colloid solution 25 is evaporated completely, as shown in FIG. 4E, the sapphire substrate 21 is taken out from the container 26, and a sapphire substrate 21 with plural nano-sized balls 22 orderly arranged thereon is obtained, as shown in FIG. 4F.

In the present embodiment, the material of the nano-sized balls 22 is poly-styrene (PS). However, the material of the nano-sized balls 22 can be ceramics, metal oxides such as TiOₓ, poly(methyl methacrylate) (PMMA), or glass material such as SiOₓ, according to different application demands. In addition, the diameters of the nano-sized balls 22 are 100 nm˜2.5 μm, and the diameters of the majority of nano-sized balls 22 are the same. However, in different application demands, the sizes of the nano-sized balls 22 are not limited to the aforementioned range.

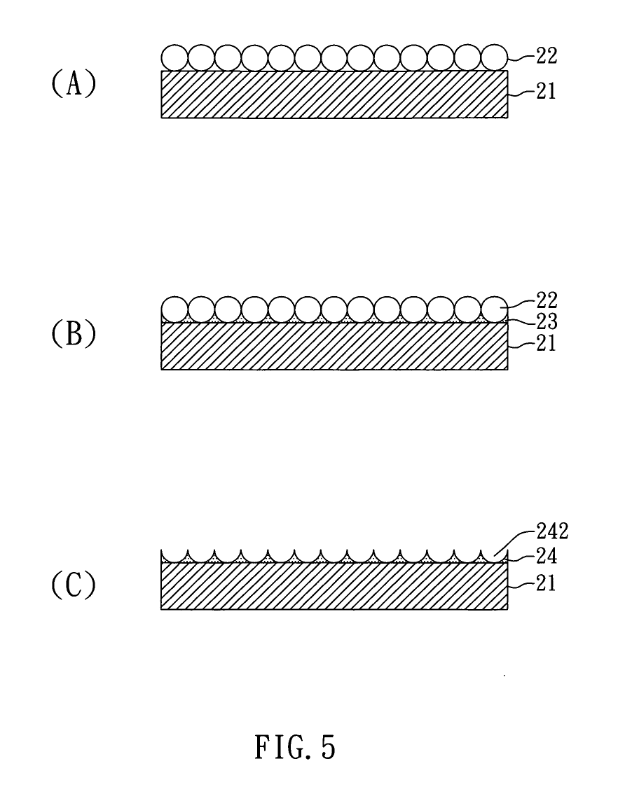

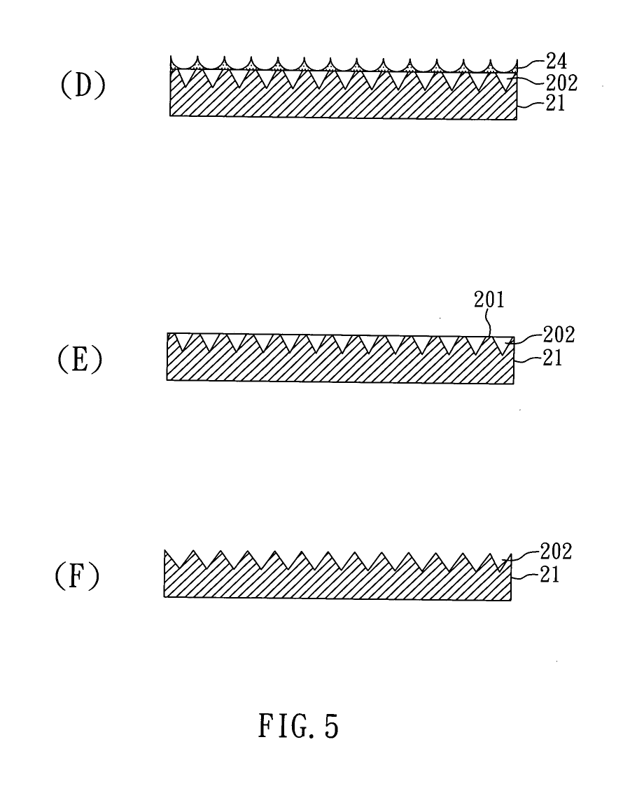

FIGS. 5A to 5F are each cross-sectional views illustrating a process for manufacturing a sapphire substrate with a periodical structure in a preferred embodiment of the present invention. First, as shown in FIG. 5A, a sapphire substrate 21 and plural nano-sized balls 22 are provided. According to the aforementioned method, the nano-sized balls 22 are arranged in order on the surface of the sapphire substrate 21 to form a nano-sized ball layer. The nano-sized balls 22 can arrange on the surface of the sapphire substrate 21 in a form of multiple layers. In the present embodiment, the nano-sized balls 22 are arranged on the surface of the sapphire substrate 21 in a form of single layer. The SEM image of the sapphire substrate 21 shows that the nano-sized balls are arranged on the surface of the sapphire substrate 21 in a form of single layer.

Next, a cladding layer is deposited on partial surface of the sapphire substrate 21 and the gaps between the nano-sized balls 22 through CVD, as shown in FIG. 5B. Herein, the thickness of the cladding layer 23 is less than the diameter of the nano-sized balls 22. Further, the material of the cladding layer 23 is silicon oxide. However, the cladding layer 23 can be formed not only by CVD, but also by PVD. Moreover, the material of the cladding layer 23 can be any kind of glass or metal material, which is ordinarily used in an etching template. For example, the material of the cladding layer can be Cr, Ta, W, V, Ni, Fe, Ag, Au, Pt, Pd, silicon nitrides, silicon oxynitrides, or silicon oxides doped with alkaline metal or alkaline-earth metal.

Then, the nano-sized balls 22 are removed by using a THF solution, and the residual cladding layer 23 serves as an etching template 24, as shown in FIG. 5C. Hence, a sapphire substrate having an etching template with a periodical structure is obtained, which comprises: a sapphire substrate 21; and an etching template 24 disposed on the surface of the sapphire substrate 21. The etching template 24 has a periodical structure formed on the surface of the etching template 24 and has plural micro-cavities 242, and the micro-cavities 242 are arranged in an array.

It should be noted that the nano-sized balls with different materials are removed from the substrate by different suitable solutions. For example, the nano-sized balls made of PMMA can be removed by toluene or formic acid, and the nano-sized balls made of SiOₓ can be removed by using HF or a solution containing HF.

Then, as shown in FIG. 5D, the cladding layer is used as an etching template 24 to pattern the sapphire substrate 21 through a method of wet etching. In the present embodiment, the etching buffer comprises sulfuric acid and phosphoric acid. However, the etching buffer used for wet etching is selected according to the material of the cladding layer. In addition, as the components and the concentration of the etching buffer, and the temperature and the time of the etching process are changed, the patterns formed on the sapphire substrate are different. Furthermore, as the temperature of etching process is increased, the etching time is decreased.

After the etching template 24 is removed, plural micro-cavities 202, i.e. a periodical structure, are formed on the surface of the sapphire substrate 21, as shown in FIG. 5F. The micro-cavities 202 are arranged in an array, and the micro-cavities 202 are in inverted awl-shape. Herein, the inverted awl means that the base of the awl is located on the surface of the sapphire substrate 21, and the apex of the awl is hollowed from the surface of the sapphire substrate 21. Further, there is a plane 201 between the adjacent two micro-cavities 202, and the plane 201 is in a same elevation. Hence, the sapphire substrate prepared in the present embodiment is a concaved sapphire substrate with a periodical structure formed thereon.

The SEM image of the patterned sapphire substrate shows that the micro-cavities each with an inverted awl-shaped are formed on the sapphire substrate in the present embodiment. The length from the side of the base to the projection point of the apex on the base is about 310 nm, and the length of the side of the base is about 410 nm. Hence, the periodical structure formed on the concave sapphire substrate of the present embodiment is a nano-sized periodical structure.

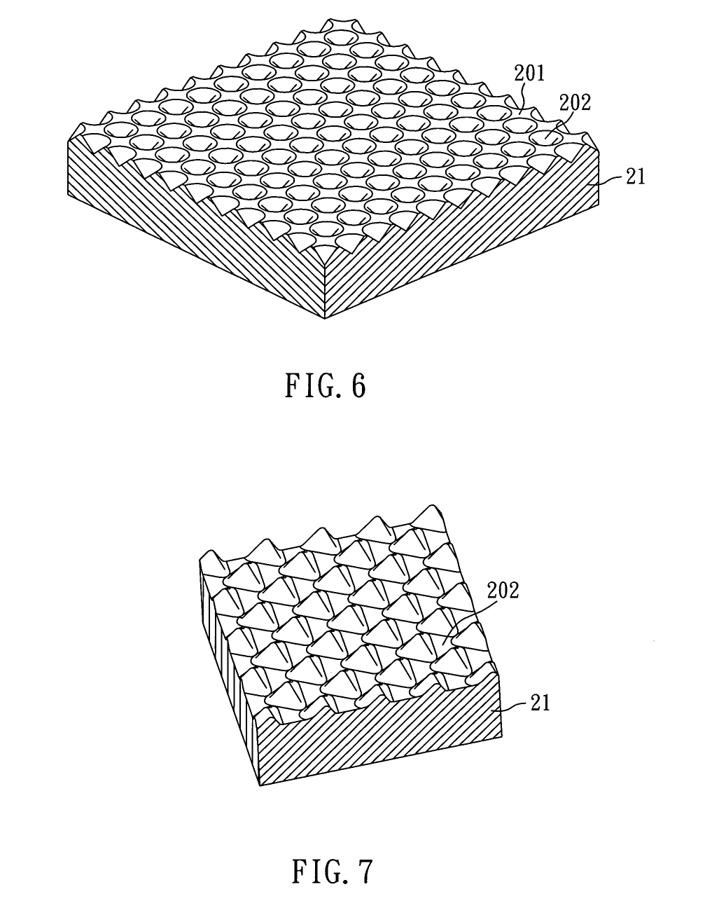

In order to understand the periodical structure formed on the concave sapphire substrate of the present embodiment, please refer to FIG. 6, which is a perspective view of a sapphire substrate with a concave periodical structure of a preferred embodiment of the present invention. The sapphire substrate with the periodical structure prepared according to the aforementioned method comprises plural micro-cavities 202, which are arranged in an array on the surface of the sapphire substrate 21 and each formed in an inverted awl-shape.

In addition, in order to increase the roughness of the surface of the sapphire substrate, re-etching the surface of the substrate 10 is performed after the concave sapphire substrate is obtained, as shown in FIG. 5F. After re-etching the concave sapphire substrate, the size of the micro-cavities is extended, and the plane between the adjacent micro-cavities is eliminated through re-etching process. Hence, a convex sapphire substrate with a periodical structure is obtained. Furthermore, the SEM image of the sapphire substrate of the present embodiment shows that there is no plane on the edges of the inverted awl-shaped micro-cavities, so the pattern on the surface of the sapphire substrate is in a convex form.

In order to understand the periodical structure formed on the convex sapphire substrate of the present embodiment, please refer to FIG. 7, which is a perspective view of a sapphire substrate with a convex periodical structure of a preferred embodiment of the present invention. After re-etching the surface of the sapphire substrate, the roughness of the surface of the sapphire substrate can be increased. When the convex sapphire substrate prepared in the present embodiment is applied to LEDs, the patterned surface of the sapphire substrate is more consistent with the expitaxial GaN thin film. Hence, the light emitting efficiency of the LEDs can also be improved.

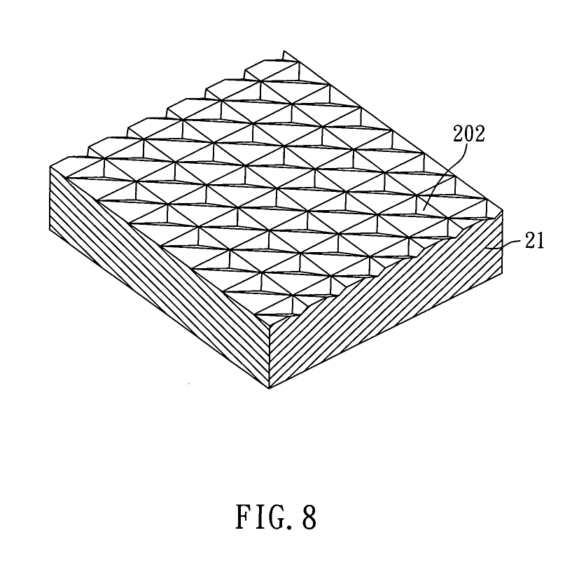

FIG. 8 is a perspective view of a sapphire substrate with a periodical structure of another preferred embodiment of the present invention. The sapphire substrate of the present embodiment is prepared by the aforementioned process. Further, the shape of the micro-cavities can be adjusted by the condition, i.e. time and temperature, of the etching process.

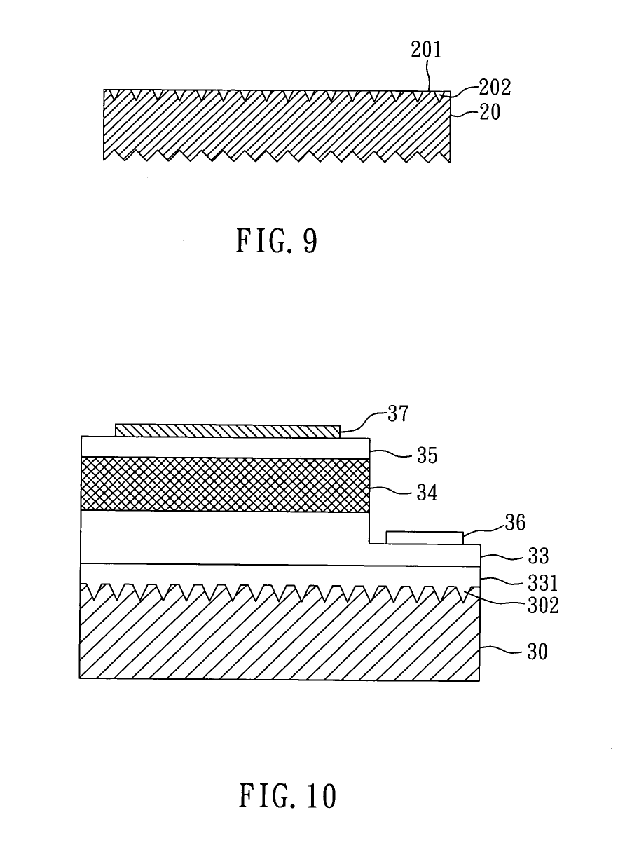

FIG. 9 is a perspective view of a sapphire substrate with a periodical structure of still another preferred embodiment of the present invention, which is formed according to the aforementioned process. There are two periodical structures formed on both surfaces of the sapphire substrate, respectively. In the present embodiment, one of the periodical structures is a concave structure, and there is a plane 201 between the adjacent micro-cavities 202. The other periodical structure is a convex structure, and there is no plane between the adjacent micro-cavities 202. However, both of the periodical structures can be convex structures or concave structures, according to the application of the sapphire substrate.

FIG. 10 is a perspective view of a sapphire substrate with a periodical structure of still another preferred embodiment of the present invention. The LED of the present embodiment is co-operated with an external electronic circuit (not shown in the figure) to transform electricity into light. The LED of the present embodiment comprises: a substrate 30, a buffer layer 331 disposed on the surface of the substrate 30, a first semiconductor layer 33 disposed on the surface of the buffer layer 331, an active layer 34 disposed on the surface of the first semiconductor layer 33, a second semiconductor layer 35 disposed on the surface of the active layer 34, a first electrical contacting part 36 electrically connected to the first semiconductor layer 33, and a second electrical contacting part 37 electrically connected to the second semiconductor layer 35.

Herein, the substrate is the sapphire substrate with the periodical structure prepared according to the aforementioned method, the buffer layer 331 is an expitaxial GaN thin film, the material of the first semiconductor layer 33 is N-type GaN, and the material of the second semiconductor layer 35 is P-type GaN. In addition, the periodical structure having micro-cavities 32 is formed on the surface of the sapphire substrate 30, so the differences of the lattice constant between sapphire (substrate 30) and GaN (the buffer layer 331) can be reduced. Compared to the LED using a sapphire substrate without a periodical structure, the brightness of the LED of the present embodiment, which comprises the sapphire substrate with the periodical structure, can be improved about 20˜40%.

The sapphire substrate with the periodical structure of the present invention can be produced in a rapid and inexpensive way, by using the nano-sized balls as an etching template. When the sapphire substrate of the present invention is applied to blue LEDs, it is possible to eliminate the phenomenon of total reflection through the periodical structure formed thereon. At the same time, the sapphire substrate with the periodical structure of the present invention is produced by a process of wet etching, so the surface of the periodical structure is a natural lattice plane. Hence, when GaN is deposited on the surface of the periodical structure of the sapphire substrate to form an expitaxial thin film, the periodical structure is consistent with the lattice constant of GaN. Therefore, when the sapphire substrate of the present invention is applied to LEDs, the brightness and light emitting efficiency can be improved. In conclusion, the sapphire substrate with the periodical structure of the present invention not only can be produced in a rapid and low cost way, but also can eliminate the phenomenon of total reflection and increase the brightness of LEDs.

Although the present invention has been explained in relation to its preferred embodiment, it is to be understood that many other possible modifications and variations can be made without departing from the scope of the invention as hereinafter claimed.

What is claimed is:

1. A sapphire substrate with a periodical structure, comprising:
a sapphire substrate; and
at least one periodical structure formed on at least one surface of the sapphire substrate, and having plural micro-cavities,
wherein, the micro-cavities are arranged in an array, the micro-cavities are each in an inverted awl-shape, the length of the base line of the micro-cavities is 100˜2400 nm, and the depth of the micro-cavities is 25˜1000 nm.

2. The sapphire substrate as claimed in claim 1, wherein the periodical structure is formed by the following steps:
(A) providing the sapphire substrate and plural nano-sized balls, wherein the nano-sized balls are arranged on a surface of the sapphire substrate;
(B) depositing a cladding layer on partial surface of the sapphire substrate and the gaps between the nano-sized balls;
(C) removing the nano-sized balls;
(D) etching the sapphire substrate by using the cladding layer as a etching template; and
(E) removing the etching template to form the periodical structure on the surface of the sapphire substrate.

3. The sapphire substrate as claimed in claim 2, wherein after the step (E) further comprises a step (F): re-etching the surface of the sapphire substrate.

4. The sapphire substrate as claimed in claim 1, wherein there is a plane between the adjacent micro-cavities.

5. The sapphire substrate as claimed in claim 1, wherein there is no plane between the adjacent micro-cavities.

6. The sapphire substrate as claimed in claim 1, comprising two periodical structures formed on two surfaces of the sapphire substrate respectively, wherein there is a plane between the adjacent micro-cavities in one periodical structure, and there is no plane between the adjacent micro-cavities in another periodical structure.

7. The sapphire substrate as claimed in claim 1, wherein the periodical structure is a nano-sized periodical structure.

8. The sapphire substrate as claimed in claim 1, further comprising an epitaxial thin film formed on the surface of the sapphire substrate and the surfaces of the micro-cavities.

9. The sapphire substrate as claimed in claim 8, wherein the epitaxial thin film is an epitaxial GaN thin film.

10. The sapphire substrate as claimed in claim 2, wherein the step
(A) of arranging the nano-sized balls on the surface of the sapphire substrate comprises the following steps:
(A1) providing the sapphire substrate, and a colloid solution in a container, wherein the colloid solution comprises the nano-sized balls and a surfactant;
(A2) placing the sapphire substrate in the container, and the colloid solution covering the surface of the sapphire substrate; and
(A3) adding a volatile solution into the container to obtain the sapphire substrate with the nano-sized balls formed thereon.

11. The sapphire substrate as claimed in claim 2, wherein the cladding layer is formed on partial surface of the sapphire substrate and the gaps between the nano-sized balls through CVD or PVD.

12. The sapphire substrate as claimed in claim 2, wherein the sapphire substrate is etched by an etching solution in the step (D).

13. The sapphire substrate as claimed in claim 12, wherein the etching solution is a combination of H₂SO₄ and H₂PO₄.

14. The sapphire substrate as claimed in claim 2, wherein the material of the cladding layer is silicon oxides, silicon nitrides, silicon oxynitrides, silicon oxides doped with alkaline metal, silicon oxides doped with alkaline-earth metal, Cr, Ta, W, V, Ni, Fe, Ag, Au, Pt, or Pd.

15. The sapphire substrate as claimed in claim 2, wherein the material of the nano-sized balls is silicon oxides, ceramics, PMMA, titanium oxides, or PS.

16. The sapphire substrate as claimed in claim 2, wherein the thickness of the cladding layer is less than the diameters of the nano-sized balls.

17. The sapphire substrate as claimed in claim 2, wherein the diameters of the nano-sized balls are 100 nm˜2.5 μm.

18. The sapphire substrate as claimed in claim 2, wherein the diameters of the nano-sized balls are the same.

19. A sapphire substrate having an etching template with a periodical structure, comprising:
a sapphire substrate; and
an etching template, disposed on a surface of the sapphire substrate,
wherein, the etching template has a periodical structure formed on the surface of the etching template and having plural micro-cavities, and the micro-cavities are arranged in an array.

20. The sapphire substrate as claimed in claim 19, wherein the micro-cavities are in half-sphere shape.

21. The sapphire substrate as claimed in claim 19, wherein the diameters of the micro-cavities are 100 nm˜2400 nm.

22. The sapphire substrate as claimed in claim 19, wherein the material of the etching template is silicon oxides, silicon nitrides, silicon oxynitrides, silicon oxides doped with alkaline metal, silicon oxides doped with alkaline-earth metal, Cr, Ta, W, V, Ni, Fe, Ag, Au, Pt, or Pd.
